(19) United States
(12) Patent Application Publication
(10) Pub. No.: US 2005/0093553 A1
(43) Pub. Date: May 5, 2005

(54) Current over-flow detector for motor driving circuit

(76) Inventor: Shou-Ming Li, Taoyuan (TW)

Correspondence Address: BIRCH STEWART KOLASCH & BIRCH, PO BOX 747, FALLS CHURCH, VA, 22040-0747, US

(21) Appl. No.: 10/898,262

(22) Filed: Jul. 26, 2004

(30) Foreign Application Priority Data
Nov. 4, 2003 (TW) 092130782

(51) Int. Cl. G01R 31/14; G01R 31/28

(52) U.S. Cl. 324/511

(57) ABSTRACT

An over current detector of a motor driver is disclosed to detect whether the current over flowing into the motor driver or not when the motor malfunctions. The detector is characterized in comprising a current transformer whose one terminal of the input side receives a rectified current, and the other terminal couples with the input terminal of the motor driver. One terminal of the output side is coupled to an input terminal of a comparator, and the other terminal is coupled to the ground. The disclosed current detector has the advantages of being reliable for current over-flow protection, quick reaction, low cost and circuit simplicity.

### BACKGROUND OF THE INVENTION

1. Field of Invention

The present invention relates to a current over-flow detector, and more particularly to a current over-flow detector used for a motor driver circuit of a permanent magnetic server motor.

2. Related Art

Current over-flow detection is important for a motor driver. Currently available current over-flow detectors include a shunt, a CT, and a Hall current detector based on Hall Effect.

The shunt operates according to Ohm's law while the CT and the Hall current detector operate according to Ampere's law. The shunt is inexpensive and usually used to measure direct and alternate currents; yet, it increases the pressure drop and provides no isolation between the driver circuit and the sensor. CT is an inexpensive sensor with isolation in between the driver circuit and a sensor; yet, it only measures an alternate current. The Hall current sensor not only is capable to be used in both open-loop and close-loop circuits, but also provides isolation between the driver circuit and the sensor; its operation frequency ranges from the direct current to the alternate current of 200 KHz; however, its application is limited due to its price, size and temperature characteristic.

Referring to FIG. 1, a current over-flow detector using the Hall current sensor includes a converter 100 and an inverter 200. The converter 100 is used to convert the alternate current into the direct current. The inverter 200 is used to invert the direct current output from the converter into the alternate current that is then output to the motor driver circuit (not shown). Three input terminals at left side of the converter 100 are for three-phase input. Three output terminals at a right side of the inverter 200 are for three-phase output. A Hall current sensor 300 couples between the converter 100 and the inverter 200. A resistor 400 further couples with the output terminals. A voltage amplifier 500 is provided to amplify the output voltage. An output terminal of the voltage amplifier 500 couples with a comparator 600 to compare the output voltage with a predetermined voltage. When the motor malfunctions or break down, a duly large current feeds back to the driver circuit, resulting in damage of the circuit. Such a large current is alerted by means of the operation of the Hall current sensor 300 and the comparator 600 and then a protection mechanism is actuated. . The detector is advantageous in providing a precise measurement of the large current; yet, it cannot accurately measure small current. Furthermore, since the detector contains iron core, not only it operates with small dynamic frequency width, when measuring fast changing current flows, it also has an output delay and flocculation as the temperature increases.

Referring to FIG. 2, the current over-flow detector includes a resistor and an optical isolator. A microresistor 410 couples between the converter 100 and the inverter 200. An optical isolation voltage amplifier 700 further couples with the microresistor 410 in parallel. One output terminal of the amplifier 700 couples with the comparator 600 for voltage comparison with a predetermined voltage. The microresistor 410 has an advantage for measuring small current quickly and precisely, with no relation to temperature change. However, the detection of current over-flow needs a very small microresistor, and cannot be achieved in such a manner.

### SUMMARY OF THE INVENTION

It is an object of the invention to provide a current over-flow detector that solves the prior problems.

In order to achieve the above and other objectives, the current over-flow detector according to this invention is used in a motor driver circuit for detection of current over-flow when the motor driver circuit is overloaded or broken down. The current over-flow detector includes a current coil consisting of two sets of coils and a current transformer made by silicon steel sheet. A first terminal at the input side of the current coil receives a rectified current. A second terminal at the input side of the current coil couples with an input terminal of the motor driver circuit. A third terminal at the output side of the current coil couples with an input terminal of a comparator. A fourth terminal at the output side of the current coil couples with the ground.

The current over-flow detector of this invention provides a reliable protection from current over flowing, responds quickly and precisely, has a simplified structure and can be manufactured at a low cost. To achieve the goal of having a detector with precise detection and quick response, this invention uses the current transformer as a current sensor and fully makes use of the low-inductance characteristic of a permanent magnetic motor and the low-current characteristic of the current transformer.

Further scope of applicability of the present invention will become apparent from the detail description given hereinafter. However, it should be understood that the detailed description and specific examples, while indicating preferred embodiments of the invention, are given as illustrations only, and various changes and modifications within the spirit and scope of the invention will become apparent to those skilled in the art.

### BRIEF DESCRIPTION OF THE DRAWINGS

The present invention will become more apparent from the detailed description given hereinbelow as an illustration only, and thus are not limitative of the present invention, and wherein:

FIG. 1 is a circuit block diagram of a conventional current over-flow detector;

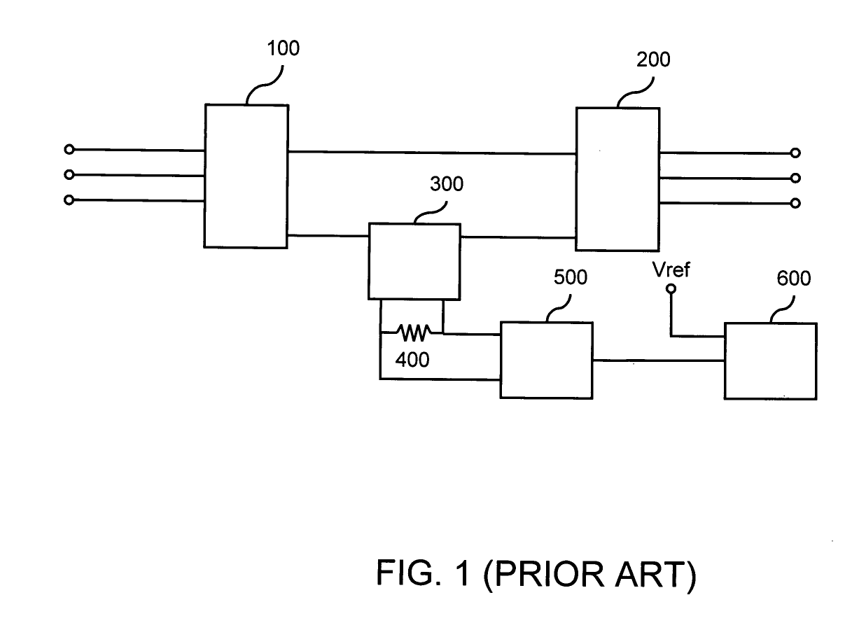

FIG. 2 is a circuit block diagram of another conventional current over-flow detector;

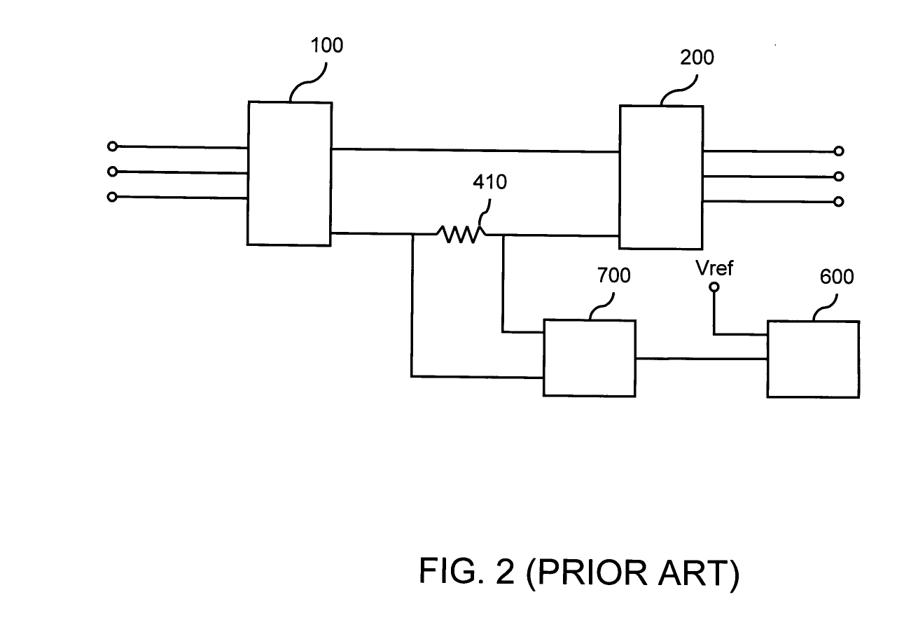

FIG. 3 is a circuit block diagram of a current over-flow detector according to one embodiment of this invention;

FIG. 4 is a circuit layout of a current over-flow detector according to one embodiment of this invention; and

FIG. 5 is a graph of current waves in a current transformer according to one embodiment of this invention.

### DETAILED DESCRIPTION OF THE INVENTION

The invention provides a current over-flow detector used to detect any current over flowing into a motor driver circuit. When the driver motor is overloaded or broken down, once a current over-flow through the driver circuit is detected, a detecting circuit of the motor driver circuit is quickly actuated.

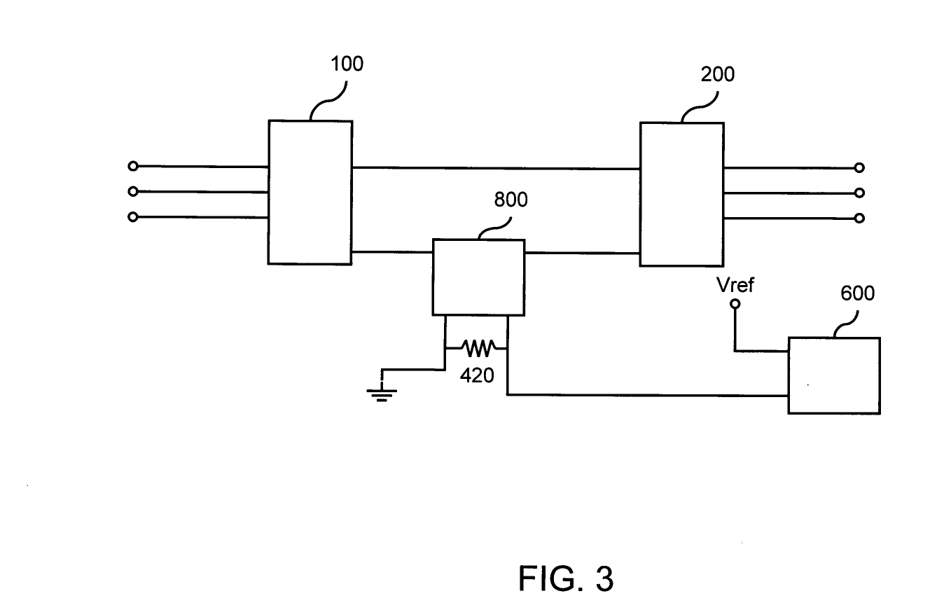

Referring to FIG. 3, the motor driver circuit includes a converter 100 and an inverter 200. The converter 100 converts an alternate voltage into a direct current. Three input terminals at the left side of the converter are for three-phase input. The inverter 200 first inverts the indirect current from the converter into the alternate current; then output the alternate current to the motor driver circuit (not shown). Three output terminals at the right side of the inverter 200 are for three-phase current output of the motor driver circuit so that the motor driver circuit outputs a driving current to load the motor.

The current over-flow detector of this invention includes a current transformer 800 coupled between the converter 100 and the inverter 200. A resistor 420 is mounted to one of the output terminals to bypass the current and protect components of the motor.

The current transformer 800 has output terminals, one of which is grounded and others are connected to an output terminal of a comparator 600 to compare the output current with a predetermined voltage. The comparator is, for example, an operation amplifier.

When the motor is in an abnormal condition, a large current or an over flowing current goes back to the driver circuit. The circuit will be protected according to the comparison results from the comparator 600. That is, when the driver circuit may be damaged due to the feedback large current, the current transformer 800 is actuated to detect the over flowing current, and the comparator 600 detects an abnormal voltage to actuate a protection mechanism.

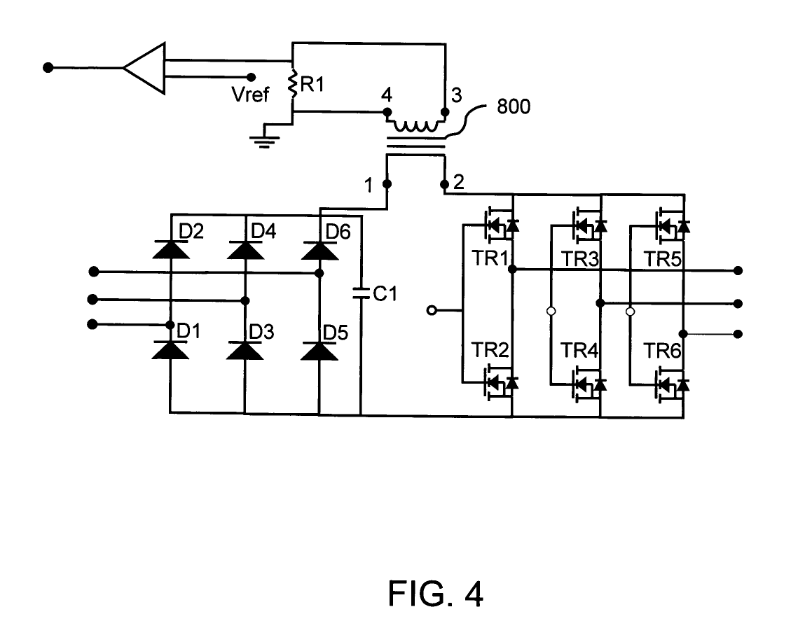

FIG. 4 is a circuit layout of an current over-flow detector according to one embodiment of this invention. A first terminal 1 at the input side of the current transformer 800 receives a rectified current. A second terminal 2 couples with an output terminal of the inverter 200. Usually, the inverter 200 is a former circuit in the motor driver circuit. A third terminal 3 couples with an input terminal of the comparator 600. A comparison voltage is input to another input terminal of the comparator 600 while a fourth terminal 4 couples with the ground.

For a three-phase alternate server motor, the current is rectified via a diode device consisting of three sets of diode in parallel. Each set of diodes includes two diodes in series. As shown in figures, a first diode D1 and a second diode D2 are connected in series; a third diode D3 and a fourth diode D4 are connected in series; and a fifth diode D5 and a sixth diode D6 are connected in series.

N-type sides of the second diode D2, fourth diode D4, and sixth diode D6 couple with the first terminal 1 of the current transformer.

The inverter 200 includes a transistor, preferably an insulation gate bi-transistor (IGBT). Two transistors in series invert one phase. As illustrated in the figures, a first transistor TR1 and a second transistor TR2 are connected in series; a third transistor TR3 and a fourth transistor TR4 are connected in series; and a fifth transistor TR5 and a sixth transistor TR6 are connected in series.

N-type sides of the second transistor TR2, fourth transistor TR4 and sixth transistor TR6 are connected to the second terminal 2 of the current transformer. The first transistor TR1, third transistor TR3, and fifth transistor TR5 are connected to P-type sides of the first diode D1, third diode D3, and fifth diode D5 respectively. A gate of each transistor couples with a gate driver circuit.

A capacitor C1 further couples with the fifth diode D5 and sixth diode D6 in parallel. A resistor R1 further couples with the third terminal 3 and fourth terminal 4 of the current transformer 800.

The current transformer performs well at both the P-type sides and N-type sides of the diodes. For example, in FIG. 4, the current transformer 800 couples with the N-type sides of the diode and the sources of the transistors.

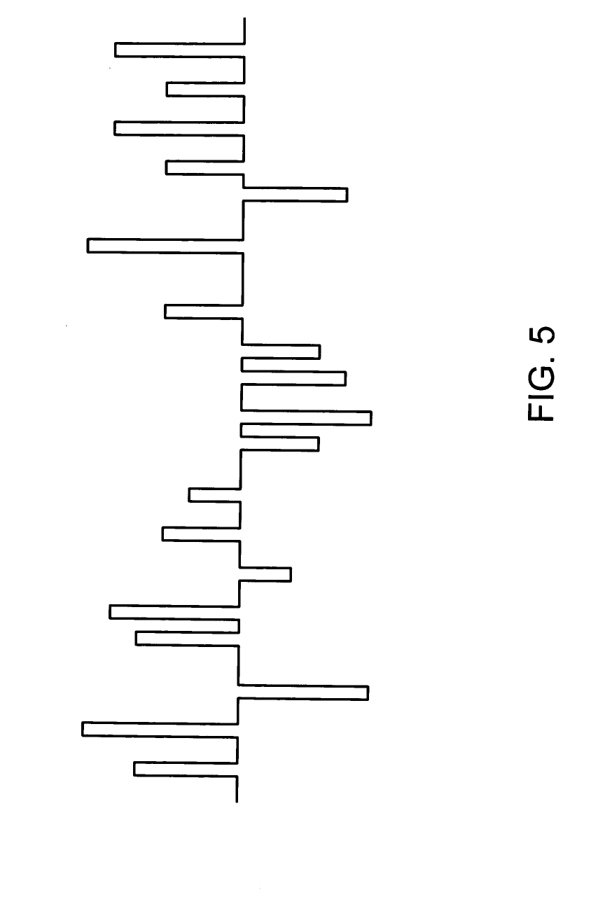

The current transformer can also function as a current detecting device. The current transformer includes two sets of coils and silicon steel sheets, which generates mutual inductance on the alternate current with quick response. However, such current transformer is not suitable for measuring current. The current is suddenly generated by a low-inductance alternate current motor, as shown in FIG. 5, which satisfies the requirement of current wave of the current transformer. On other isolation terminals of the current transformer also generates a similar current wave. Thereby, the motor can be well protected from being damaged due to the current over-flow.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A current over-flow detector for a motor driver circuit, for detecting any current over flowing through the motor driver circuit when the motor driver circuit is overloaded or broken down, the current over-flow detector is characterized in comprising:
a current transformer, a first terminal at an input side thereof receiving a rectified current, a second terminal at the input side thereof coupling with an input terminal of the motor driver circuit, a third terminal at an output side thereof coupling with an input terminal of a comparator, and a fourth terminal at output side thereof coupling with the ground.

2. The current over-flow detector of claim 1, wherein the current transformer includes two sets of coils and silicon steel sheets.

3. The current over-flow detector of claim 1, wherein a capacitor further couples with the input side of the current transformer in parallel.

4. The current over-flow detector of claim 1, wherein a resistor further couples with the output side of the current transformer in parallel.

5. The current over-flow detector of claim 1, wherein the comparator is an operation amplifier.

6. A current over-flow detector for a motor driver circuit, used to detect any over current passing through the motor driver circuit when the motor driver circuit is overloaded or broken down, the current over-flow detector is characterized in comprising:
a current transformer, a first terminal at an input side thereof coupling with a rectifying circuit, a second terminal at the input side thereof coupling with a set of transistors, a third terminal at an output side thereof coupling with an input terminal of a comparator, and a fourth terminal at the output side thereof coupling with the ground.

7. The current over-flow detector of claim 6, wherein the current transformer includes two sets of coils and silicon steel sheets.

8. The current over-flow detector of claim 6, wherein a capacitor further couples with the input side of the current transformer in parallel.

9. The current over-flow detector of claim 6, wherein a resistor further couples with the output side of the current transformer in parallel.

10. The current over-flow detector of claim 6, wherein the comparator is an operation amplifier.

11. The current over-flow detector of claim 6, wherein the rectifying circuit consists of three sets of diodes connected in parallel.

12. The current over-flow detector of claim 6, wherein each set of diodes includes two diodes connected in series.

13. The current over-flow detector of claim 6, wherein the set of transistors includes three transistors connected in parallel.

14. The current over-flow detector of claim 6, wherein the transistor is an insulation gate bi-transistor (IGBT).

15. The current over-flow detector of claim 6, wherein the set of transistors includes two transistors connected in series.

16. The current over-flow detector of claim 15, wherein the transistor is an insulation gate bi-transistor (IGBT).
